(19) United States
(12) Patent Application Publication
(10) Pub. No.: US 2026/0130211 A1
(43) Pub. Date: May 7, 2026

(54) ELECTRONIC DEVICE

(71) Applicant: Advanced Semiconductor Engineering, Inc., Kaohsiung (TW)

(72) Inventor: Fu-Kuei CHEN, Kaohsiung (TW)

(73) Assignee: Advanced Semiconductor Engineering, Inc., Kaohsiung (TW)

(21) Appl. No.: 18/940,710

(22) Filed: Nov. 7, 2024

(51) Int. Cl. H01L 23/367; H01L 23/00; H01L 23/427; H01L 23/66; H05K 1/02

(52) U.S. Cl. CPC H10W 40/22; H05K 1/0203; H05K 1/0243; H10W 44/20; H05K 2201/09063; H05K 2201/10098; H10W 40/73; H10W 44/248; H10W 44/255; H10W 70/60; H10W 70/6528; H10W 90/00; H10W 90/724

(57) ABSTRACT

The present disclosure provides an electronic device. The electronic device includes a die, a thermal dissipation structure, and an encapsulant. The thermal dissipation structure is disposed over the die. The thermal dissipation structure has a thickness tapered along a direction far from the die. The encapsulant encapsulates the die and the thermal dissipation structure. An upper surface of the thermal dissipation structure is exposed by the encapsulant.

### BACKGROUND

### 1. Technical Field

The present disclosure relates to an electronic device.

### 2. Description of the Related Art

In the manufacture of semiconductor devices, heat dissipation is of primary concern. In conventional devices, a heat dissipating element may be connected to a die to increase the area of heat dissipation. However, in more advanced devices, packaging constraints can impede paths of dissipation, negatively impacting heat dissipation efficacy.

### SUMMARY

In some arrangements, an electronic device includes a substrate, an antenna, and a heat dissipating structure. The substrate has a first side and a second side opposite to the first side. The antenna is disposed over the first side of the substrate and includes a radiator. The heat dissipating structure is disposed under the second side of the substrate. The heat dissipating structure has a first surface functioning as a reflector of the antenna. The reflector and the radiator are collective configured to build a constructive interference of an electromagnetic wave.

In some arrangements, an electronic device includes an electronic component, an antenna, and a non-signal transmitting conductive structure. The antenna is electrically connected to the electronic component. The non-signal transmitting conductive structure has a first region configured to transmit a heat between the electronic component and the non-signal transmitting conductive structure along a first path and a second region configured to reflect an electromagnetic wave from the antenna along a second path. The first path is free from overlapping the second path

In some arrangements, an electronic device includes a carrier, an electromagnetic radiation structure, and a heat dissipating structure. The electromagnetic radiation structure includes a radiator and a reflector. The carrier defines an opening configured to accommodate the reflector and the heat dissipating structure.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1A is a cross-section of an electronic device in accordance with some arrangements of the present disclosure.

FIG. 1B is a bottom view of the electronic device as shown in FIG. 1A in accordance with some arrangements of the present disclosure.

FIG. 2 is a cross-section of a thermal dissipating structure in accordance with some arrangements of the present disclosure.

FIG. 3 is a cross-section of an electronic device in accordance with some arrangements of the present disclosure.

FIG. 4 is a cross-section of an electronic device in accordance with some arrangements of the present disclosure.

FIG. 5 is a cross-section of an electronic device in accordance with some arrangements of the present disclosure.

FIG. 6 is a chart illustrating the relation between antenna gain and frequency of antennas.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

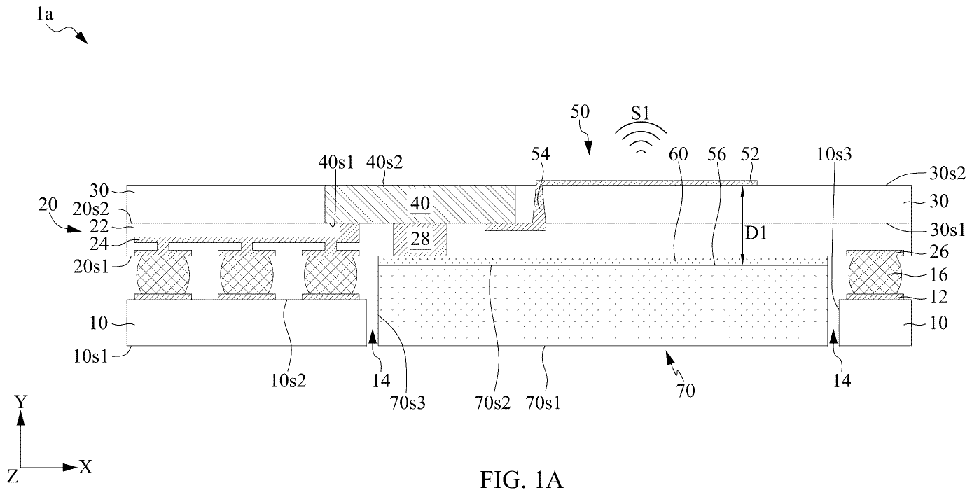

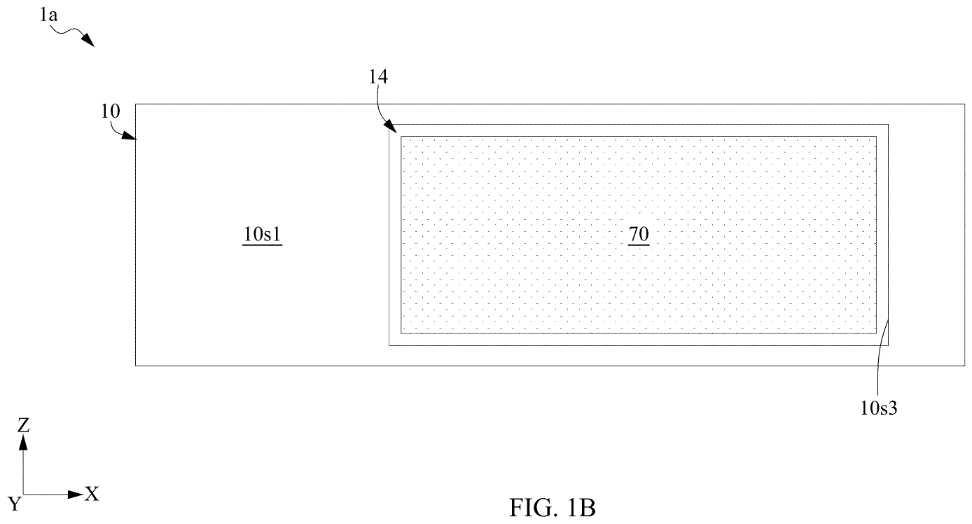

FIG. 1A is a cross-section of an electronic device 1a, and FIG. 1B is a bottom view of the electronic device 1a as shown in FIG. 1A in accordance with some arrangements of the present disclosure.

The Figure shows electronic device 1a, which includes carrier 10, redistribution structure 20, substrate 30, electronic component 40, antenna structure 50, connection layer 60, and heat dissipating structure 70.

The carrier 10 may be a flexible substrate or a rigid substrate, depending upon application. The carrier 10 may include, for example, a printed circuit board (PCB) or a flexible printed circuit board (FPCB), such as a paper-based copper foil laminate, a composite copper foil laminate, or a polymer-impregnated glass-fiber-based copper foil laminate. The carrier 10 may include an interconnection structure, such as a redistribution layer (RDL) or a grounding element. The carrier 10 may have a surface 10s1 (or a lower surface), a surface 10s2 (or an upper surface) opposite to the surface 10s1, and a surface 10s3 (or lateral surface) extending between the surfaces 10s1 and 10s2. The carrier 10 may include pads 12 over or abutting the surface 10s2. In some arrangements, the electronic device 1a may include electrical connections (not shown), such as reflowable materials or solder material, under the surface 10s1 of the carrier 10. The electrical connections may provide a connection between the electronic device 1a and an external device, such as a die, a circuit board, a package, or other components.

In some arrangements, the redistribution structure 20 may be disposed on or over the surface 10s2 of the carrier 10. In some arrangements, the redistribution structure 20 may include a dielectric structure 22 and conductive features 24 (e.g., metallic layers, conductive vias, and the like) within the dielectric structure 22. In some arrangements, the dielectric structure 22 may include polyimide, polypropylene, or other suitable materials. The redistribution structure 20 may have a surface 20s1 (or a lower surface) facing the carrier 10 and a surface 20s2 (or an upper surface) opposite to the surface 20s1. The redistribution structure 20 may include pads 26 under or within the surface 20s1.

In some arrangements, the electronic device 1a may include electrical connectors 16 between the carrier 10 and the redistribution structure 20. In some arrangements, the pads 26 may be electrically connected to the pads 12 through the electrical connectors 16. The electrical connectors 16 may include a reflowable material and/or a solder material. In some arrangements, the electrical connectors 16 may include solder balls, conductive bumps, or the like. The electrical connectors 16 may include alloys of gold and tin solder or alloys of silver and tin solder, or other suitable materials.

In some arrangements, the substrate 30 may be disposed on or over the surface 20s2 of the redistribution structure 20. In some arrangements, the substrate 30 may be configured to accommodate the electronic component 40. In some arrangements, the substrate 30 may be configured to support and/or accommodate the antenna structure 50. In some arrangements, the material of the substrate 30 may be different from that of the dielectric structure 22. In some arrangements, the substrate 30 may include glass, derivative of glass, or other suitable materials. The substrate 30 may have a surface 30s1 (or a lower surface) facing the redistribution structure 20 and a surface 30s2 (or an upper surface) opposite to the surface 30s1. In some arrangements, the surface 30s2 of the substrate 30 may be relatively flat. For example, the surface roughness of the surface 30s2 of the substrate 30 may be less than that of the surface 20s1 of the redistribution structure 20. In some arrangements, the surface roughness of the surface 30s2 of the substrate 30 may be less than that of the surface 10s2 of the carrier 10.

In some arrangements, the electronic component 40 may be at least partially embedded within the substrate 30. In some arrangements, the electronic component 40 may be configured to transmit a feed signal to the antenna structure 50. In some arrangements, the electronic component 40 may be configured to switch the antenna structure 50. In some arrangements, the electronic component 40 may include a radio frequency integrated circuit (RFIC), an application-specific IC (ASIC), a central processing unit (CPU), a microprocessor unit (MPU), a graphics processing unit (GPU), a microcontroller unit (MCU), a field-programmable gate array (FPGA), a monolithic microwave integrated circuit (MMIC), or another type of IC. In some arrangements, the electronic component 40 may include an analog to digital converter, a digital to analog converter, a switch, a mixer, a low noise amplifier (LNA), and/or other integrated circuits. In some arrangements, the electronic component 40 may have a surface 40s1 (or a lower surface) and a surface 40s2 (or an upper surface) opposite to the surface 40s1. In some arrangements, the surface 40s1 of the electronic component 40 may be substantially aligned with the surface 30s1 of the substrate 30. In some arrangements, the surface 40s2 of the electronic component 40 may be substantially aligned with the surface 30s2 of the substrate 30. Although FIG. 1A illustrates the surface 40s1 (or surface 40s2) exposed by the substrate 30, the surface 40s1 (or surface 40s2) may, in other embodiments, be covered by the substrate 30.

In some arrangements, the antenna structure 50 (or antenna or electromagnetic radiation structure) may be configured to transmit a signal S1 (e.g., an electromagnetic wave). In some arrangements, the antenna structure 50 may be configured to receive a signal. In some arrangements, the antenna structure 50 may include a radiator 52, a feed line 54, and a reflector 56.

In some arrangements, the radiator 52 and the reflector 56 may collectively generate or build constructive interference of electromagnetic waves. The radiator 52 may be configured to transmit a signal (e.g., a feed signal, an input signal, or an electromagnetic wave) toward the reflector 56. In some arrangements, the feed line 54 may be electrically coupled between the electronic component 40 and the radiator 52. In some arrangements, the feed line 54 may be configured to transmit a feed signal to the radiator 52. In some arrangements, the radiator 52 and the reflector 56 are disposed on opposite sides (e.g., surfaces 30s1 and 30s2) of the substrate 30. For example, the radiator 52 may be disposed on or over the surface 30s2 of the substrate 30, and the reflector 56 may be disposed on or under the surface 30s1 of the substrate 30. In some arrangements, the reflector 56 and the radiator 52 may be configured to generate constructive interference of electromagnetic waves. The radiator 52, feed line 54, and the reflector 56 may include copper, nickel, aluminum, gold, silver, titanium, tungsten, a combination thereof, or other suitable materials.

In some arrangements, the connection layer 60 may be disposed on or under the surface 20s1 of the redistribution structure 20. The connection layer 60 may be configured to attach the heat dissipating structure 70 to the redistribution structure 20. The connection layer 60 may include adhesive or glue, which may be cured after curing or heating. In some arrangements, the connection layer 60 may include a thermal interface material (TIM).

In some arrangements, the heat dissipating structure 70 may be disposed on or under the surface 20s1 of the redistribution structure 20. In some arrangements, the heat dissipating structure 70 may be disposed on or under the surface 30s1 of the substrate 30. In some arrangements, the heat dissipating structure 70 may laterally overlap the carrier 10. In some arrangements, the heat dissipating structure 70 may overlap the carrier 10 along the X direction. The heat dissipating structure 70 may be attached to the redistribution structure 20 through the connection layer 60. In some arrangements, the heat dissipating structure 70 may be configured to transmit heat of the electronic device 1a to the surroundings. The heat dissipating structure 70 may have a surface 70s1 (or a lower surface), a surface 70s2 (or an upper surface) opposite to the surface 70s1, and a surface 70s3 (or a lateral surface) extending between the surface 70s1 and surface 70s2. In some arrangements, the heat dissipating structure 70 may be thermally coupled to the electronic component 40. In some arrangements, the heat dissipating structure 70 may be thermally coupled to the electronic component 40 by a thermally conductive structure 28 (or thermally conductive feature). In some arrangements, the heat dissipating structure 70 may include a vapor chamber. In some arrangements, the heat dissipating structure 70 may include a heat pipe.

In some arrangements, the thermally conductive structure 28 may be thermally coupled between the electronic component 40 and the heat dissipating structure 70. The thermally conductive structure 28 may be configured to transmit heat from the connection layer 60 to the heat dissipating structure 70. In some arrangements, the thermally conductive structure 28 may be disposed within the redistribution structure 20. In some arrangements, the thermally conductive structure 28 may include a conductive via which at least partially penetrates the redistribution structure 20.

Referring to FIG. 1B, the carrier 10 may define a cavity 14 (or opening) for accommodating the heat dissipating structure 70. In some arrangements, the surface 10s3 of the carrier 10 may define the cavity 14. The surface 70s1 of the heat dissipating structure 70 may be exposed the carrier 10. In some arrangements, the heat dissipating structure 70 may be spaced apart from the carrier 10. For example, the heat dissipating structure 70 and the carrier 10 may have a non-zero distance therebetween. In some arrangements, the carrier 10 may surround or fully enclose the heat dissipating structure 70. Referring back to FIG. 1A, the surface 70s3 of the heat dissipating structure 70 may face the carrier 10. In some arrangements, the surface 70s3 of the heat dissipating structure 70 may be spaced apart from the carrier 10. In some arrangements, the surface 70s1 of the heat dissipating structure 70 may be exposed to air. In some arrangements, the surface 70s3 of the heat dissipating structure 70 may be exposed to air, enhancing the thermal transmittance ability of the electronic device 1a.

In some arrangements, the surface 70s2 of the heat dissipating structure 70 may function as a reflector of the antenna structure 50. For example, the surface 70s2, under the radiator 52, of the heat dissipating structure 70 may function as the reflector 56. In some arrangements, a portion of the surface 70s2 of the heat dissipating structure 70 and the radiator 52 may be configured to generate constructive interference of electromagnetic waves. In some arrangements, a distance D1 between the surface 70s2 of the heat dissipating structure 70 and the radiator 52 may be λ/4 of the wavelength of the signal S1 or other distances that may allow the surface 70s2 of the heat dissipating structure 70 and the radiator 52 to generate constructive interference of electromagnetic waves. In some arrangements, the reflector 56 may be configured to be electrically coupled to ground. The reflector 56 may be electromagnetically coupled to a signal (e.g., a feeding signal, an input signal, or an electromagnetic wave), and thereby transmit an output signal.

In some arrangements, the reflector 56 may be free from vertically overlapping the carrier 10 or free from overlapping the carrier 10 along the Y direction. In some arrangements, the reflector 56 may be free from vertically overlapping the electrical connectors 16 or free from overlapping the electrical connectors 16 along the Y direction. In some arrangements, the electrical connectors 16 may surround the heat dissipating structure 70. In some arrangements, the electrical connectors 16 may surround the reflector 56.

In this arrangement, no electrical signal, such as a power signal, an input/output signal or the like, passes through the heat dissipating structure 70. In this arrangement, the heat dissipating structure 70 may function as a non-signal transmitting conductive structure, which is configured to transmit heat and reflect an electromagnetic waves(s).

In a comparative example, the reflector of an antenna may be placed within or incorporated into a circuit board. In this scenario, the distance between the reflector and radiator is constrained by the thicknesses of solder balls and the circuit board, which reduces the bandwidth of the electromagnetic wave emitted by the antenna. In this embodiment, the reflector 56 may be separate from the carrier 10, addressing the aforementioned issues. Additionally, in this embodiment, the reflector 56 may be integrated with the heat dissipating structure 70, improving the thermal transmissivity of the electronic device 1a.

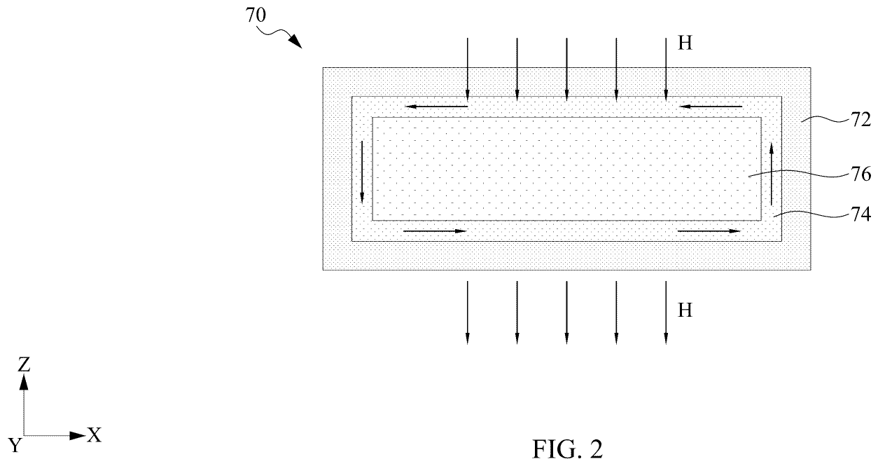

FIG. 2 is a cross-section of the heat dissipating structure 70 in accordance with some arrangements of the present disclosure. In some arrangements, the heat dissipating structure 70 may include an outer portion 70a, a middle portion 70b, and an inner portion 70c.

In some arrangements, the outer portion 70a may be configured to transmit heat H to the middle portion 70b. In some arrangements, the outer portion 70a may include metallic material, such as copper, aluminum, gold, silver, or other suitable materials. In some arrangements, a portion of the surface of the outer portion 70a may function as the radiator of an antenna. The middle portion 70b may include a working fluid. In some arrangements, the inner portion 70c may include a capillary wick structure, which may include metal capillary wicks disposed within the inner portion 70c. In some arrangements, the working fluid may be vaporized in the hot zone (not shown) and transfers heat to the cool condensation zone (not shown). The condensed liquid may return to the hot zone via a capillary wick structure to complete the heat circulation.

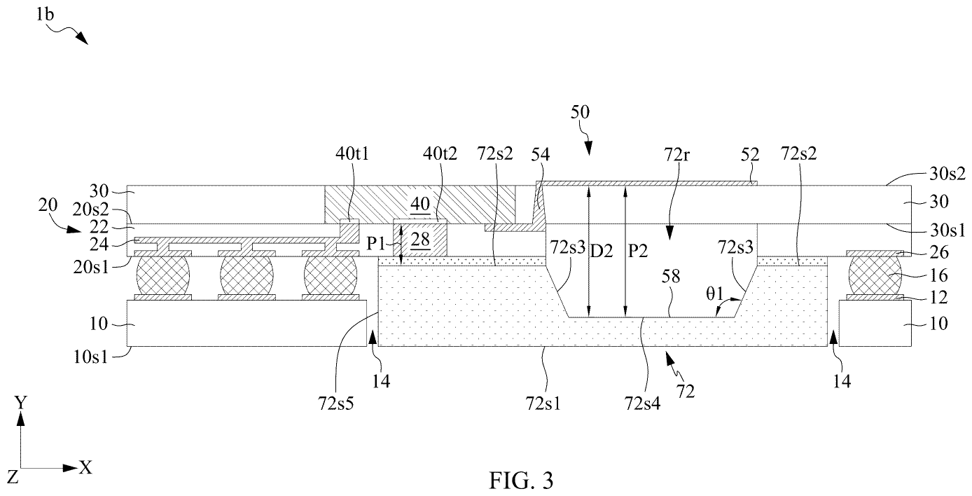

FIG. 3 is a cross-section of an electronic device 1b in accordance with some arrangements of the present disclosure. The electronic device 1b is similar to the electronic device 1a in FIG. 1A, differing only as follows.

In some arrangements, the electronic device 1b may include a heat dissipating structure 72. In some arrangements, the heat dissipating structure 72 may be disposed on or under the surface 20s1 of the redistribution structure 20. In some arrangements, the heat dissipating structure 72 may be configured to transmit heat of the electronic device 1b to the surroundings. The heat dissipating structure 72 may have a surface 72s1 (or a lower surface), a surface 72s2 (or an upper surface) opposite to the surface 72s1, and a surface 72s3 (or a lateral surface) connected to the surface 72s2, and a surface 72s4 (or an upper surface) connected to the surface 72s3. The elevation of the surface 72s4 may be different from that of the surface 72s2 with respect to the substrate 30. For example, the distance between the surface 30s1 of the substrate 30 and the surface 72s4 may be greater than the distance between the surface 30s1 of the substrate 30 and the surface 72s2. The surface 72s3 may extend between the surface 72s2 and the surface 72s4, and function as a connecting portion connecting the surfaces 72s2 and 72s4. In some arrangements, the surface 72s3 may be exposed to air. In some arrangements, the surface 72s4 may be exposed to air. In some arrangements, the surface 72s3 may be free of the connection layer 60. In some arrangements, the surface 72s4 may be free of the connection layer 60. In some arrangements, the heat dissipating structure 72 may include an outer portion, a middle portion, and an inner portion as shown in FIG. 2. The heat dissipating structure 72 may have a surface 72s5 (or a lateral surface) extending between the surfaces 72s1 and 72s2. The surface 72s5 may be exposed to air.

In some arrangements, a portion of the surface 20s1 of the redistribution structure 20 may be exposed to air. In some arrangements, a portion of the surface 20s1 of the redistribution structure 20 may be free of the connection layer 60.

In some arrangements, the heat dissipating structure 72 may be thermally coupled to the electronic component 40. The thermally conductive structure 28 may be thermally coupled between the surface 72s2 of the heat dissipating structure 72 and the electronic component 40.

In some arrangements, the heat dissipating structure 72 may define a recess 72r (or cavity) recessed from the surface 72s2 or recessed toward a direction far from the substrate 30. In some arrangements, the surface 72s3 and surface 72s4 may define the recess 72r. The surface 72s3 may serve as the sidewall, and the surface 72s4 may serve as the bottom of the recess 72r. In some arrangements, the surface 72s3 may be angled or slanted with respect to the surface 72s4. For example, an angle θ1 between the surface 72s3 and the surface 72s4 may include an obtuse angle. In some arrangements, the angle θ1 may be greater than 90°. In some arrangements, the angle θ1 may be between 90° and 115°, such as 90°, 95°, 100°, 103°, 106°, 109°, 112°, or 115°. In some arrangements, the surface 72s3 may be exposed to recess 72r. In some arrangements, the surface 72s4 may be exposed to recess 72r. In some arrangements, the surface 72s3 may be angled with respect to the surface 72s2. In some arrangements, a portion of the redistribution structure 20 may be removed to define the 72r. In some arrangements, a lateral surface (e.g., inner sidewall) of the redistribution structure 20 may be exposed to the recess 72r. In some arrangements, a portion of the surface 30s1 of the substrate 30 may be exposed to the recess 72r. In some arrangements, a lateral surface (e.g., inner sidewall) of the redistribution structure 20 may be exposed to air. In some arrangements, a portion of the surface 30s1 of the substrate 30 may be exposed to air.

In some arrangements, the surface 72s4 of the heat dissipating structure 72 may function as a reflector of the antenna structure 50. For example, the surface 72s4 of the heat dissipating structure 72 may function as a reflector 58. In some arrangements, the surface 72s4 and the radiator 52 may be configured to generate constructive interference of electromagnetic waves. In some arrangements, a distance D2 between the surface 72s4 of the heat dissipating structure 72 and the radiator 52 may be λ/4 of the wavelength of the electromagnetic wave emitted by the antenna structure 50 or other distances that may allow the surface 72s4 of the heat dissipating structure 72 and the radiator 52 to generate constructive interference of electromagnetic waves. In some arrangements, the surface 72s3 may be angled with respect to the reflector 58, which may define a horn reflector, enhancing the gain of the antenna structure 50.

In this arrangement, the heat dissipating structure 72 may function as a non-signal transmitting conductive structure. In some arrangements, the first region (e.g., the surface 72s2) of the heat dissipating structure 72 may be configured to provide a path P1 for receiving heat from the electronic component 40 along the Y direction. The path P1 may indicate a heat dissipating path between the electronic component 40 and the surface 70s2 of the heat dissipating structure 72. In some arrangements, the second region (e.g., the surface 72s4) of the heat dissipating structure 72 may be configured to provide a path P2 for reflecting an electromagnetic wave, along the Y direction, from the radiator 52. The path P2 may indicate an electromagnetic wave transmission path between the radiator 52 and the surface 70s4 of the heat dissipating structure 72. In some arrangements, the path P1 is free from overlapping the path P2. For example, the path P1 may be free from overlapping the P2 along the Y direction and the Z direction. In this arrangement, the heat dissipating structure and the reflector are integrated, which reduces dimensions (e.g., thickness) of the electronic device 1b.

In some arrangements, the electronic component 40 may include a terminal 40t1 connected to the redistribution structure 20. The terminal 40t1 may be configured to transmit a signal. In some arrangements, the electronic component 40 may include a terminal 40t2 connected to the redistribution structure 20, and the terminal 40t2 may be configured to transmit heat through the thermally conductive structure 28.

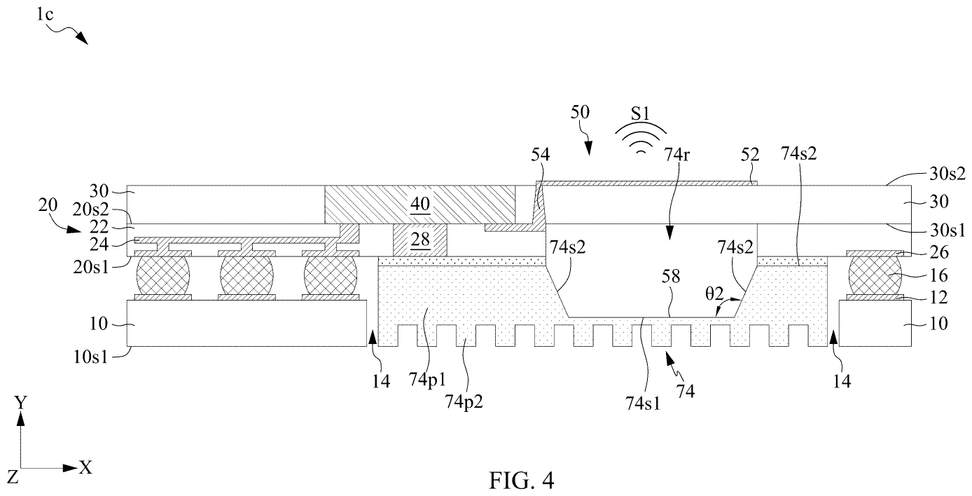

FIG. 4 is a cross-section of an electronic device 1c in accordance with some arrangements of the present disclosure. The electronic device 1c is similar to the electronic device 1a in FIG. 1A, differing only as follows.

In some arrangements, the electronic device 1c may include a heat dissipating structure 74. In some arrangements, the heat dissipating structure 74 may be disposed on or under the surface 20s1 of the redistribution structure 20. In some arrangements, the heat dissipating structure 74 may be configured to transmit heat of the electronic device 1c to the surroundings. In some arrangements, the heat dissipating structure 74 may include a heat sink. For example, the heat dissipating structure 74 may include a base portion 74p1 and protruding portions 74p2. The protruding portions 74p2 may be protruded from the base portion 74p1. In some arrangements, the base portion 74p1 may be disposed between the protruding portions 74p2 and the substrate 30. In some arrangements, the base portion 74p1 may be disposed between the protruding portions 74p2 and the antenna structure 50.

In some arrangements, the heat dissipating structure 74 may define a recess 74r (or cavity). The heat dissipating structure 74 may include a surface 74s1 and a surface 74s2 defining the recess 74r. In some arrangements, the surface 74s1 of the heat dissipating structure 74 may function as a reflector of the antenna structure 50. For example, the surface 74s1 of the heat dissipating structure 74 and the radiator 52 may be configured to generate constructive interference of electromagnetic waves. In some arrangements, the surface 74s2 may be angled with respect to the surface 74s1. For example, an angle θ2 between the surface 74s2 and the surface 74s1 may be between 100° and 115°, such as 100°, 103°, 106°, 109°, 112°, or 115°.

In some arrangements, a portion of the redistribution structure 20 may be removed to define the recess 74r. For example, a portion of the dielectric structure 22 may be removed to define the recess 74r. In some arrangements, a portion of the surface 30s1 may be exposed to the recess 74r. In some arrangements, a portion of the surface 30s1 may be exposed to air.

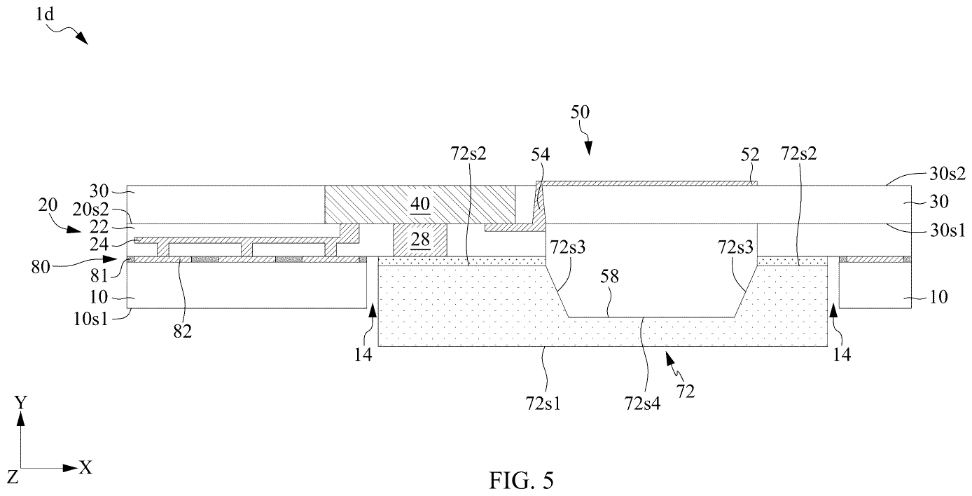

FIG. 5 is a cross-section of an electronic device 1d in accordance with some arrangements of the present disclosure. The electronic device 1d is similar to the electronic device 1b in FIG. 3, differing only as follows.

In some arrangements, the electronic device 1d may include a hybrid-bond structure 80. The hybrid-bond structure 80 may be disposed between the carrier 10 and the redistribution structure 20. In some arrangements, the hybrid-bond structure 80 may include a structure involving a bonding between dielectric materials and another bonding between metallic materials. For example, the hybrid-bond structure 80 may include a dielectric bonding structure 81 and a conductive bonding structure 82. The dielectric bonding structure 81 may include oxide or other suitable materials. The dielectric bonding structure 81 may be formed by bonding two dielectric layers. The conductive bonding structure 82 may include copper or other suitable materials. The conductive bonding structure 82 may be formed by bonding two conductive layers. Since the hybrid-bond structure 80 may occupy smaller volume, further reducing dimensions (e.g., thickness) of the electronic device 1d.

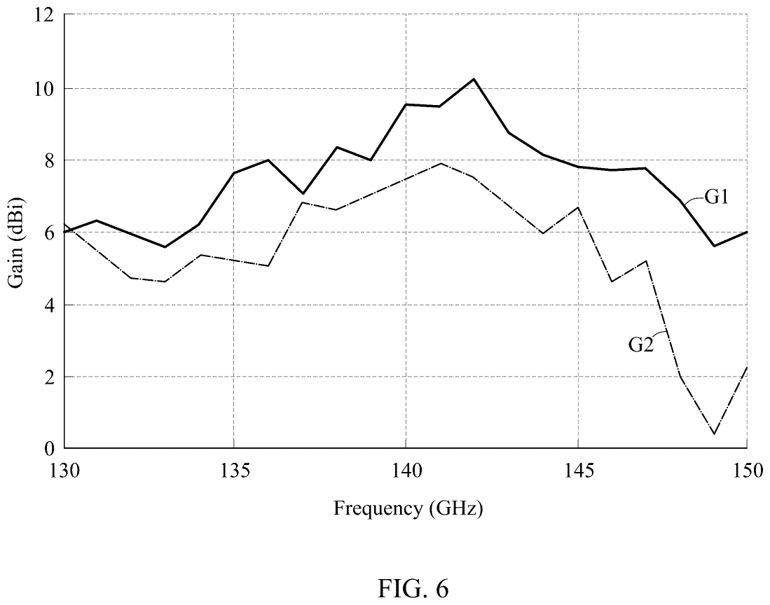

FIG. 6 is a chart illustrating the relation between antenna gain and frequency of antennas. The X-axis indicates frequency of an electromagnetic wave from an antenna. The Y-axis indicates the gain of the electromagnetic wave from an antenna. Line G1 illustrates the relation between antenna gain and the frequency of a horn antenna, which may include a horn reflector. Line G2 illustrates the relation between antenna gain and the frequency of a planar antenna. As shown in FIG. 6, the gain of the horn antenna is better than that of the planar antenna. Therefore, the electronic device of the present disclosure may exhibit improved gain.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a substrate having a first side and a second side opposite to the first side;
an antenna disposed over the first side of the substrate and comprising a radiator; and
a heat dissipating structure disposed under the second side of the substrate,
wherein the heat dissipating structure has a first surface functioning as a reflector of the antenna, and the reflector and the radiator are collective configured to build a constructive interference of an electromagnetic wave.

2. The electronic device of claim 1, wherein the substrate and the heat dissipating structure define a cavity, wherein a distance between the first surface and the radiator is λ/4 of a wavelength of the electromagnetic wave.

3. The electronic device of claim 1, wherein the heat dissipating structure defines a cavity recessed toward a direction far from the substrate.

4. The electronic device of claim 3, wherein the heat dissipating structure comprises a second surface connected to the first surface, the first surface and the second surface collectively define the recess, and the second surface is slanted with respect to the first surface.

5. The electronic device of claim 4, wherein the second surface and the first surface define an angle greater than 90 degrees.

6. The electronic device of claim 4, wherein the heat dissipating structure comprises a third surface facing the substrate and a fourth surface connected to the third surface, and the fourth surface is exposed to air.

7. The electronic device of claim 4, further comprising:
a carrier electrically connected to the substrate, wherein the carrier laterally overlaps the heat dissipating structure and is spaced apart from the heat dissipating structure.

8. The electronic device of claim 1, further comprising:
a thermally conductive feature thermally coupled between an electronic component and
the heat dissipating structure.

9. The electronic device of claim 8, further comprising:
a carrier electrically connected to the substrate by a redistribution structure, and the thermally conductive feature is disposed within the redistribution structure.

10. An electronic device, comprising:
an electronic component;
an antenna electrically connected to the electronic component; and
a non-signal transmitting conductive structure having a first region configured to transmit a heat between the electronic component and the non-signal transmitting conductive structure along a first path and a second region configured to reflect an electromagnetic wave from the antenna along a second path, wherein the first path is free from overlapping the second path.

11. The electronic device of claim 10, further comprising:
a carrier electrically connected to the electronic component, wherein the first region is located at an elevation different from an elevation of the second region with respect to the carrier.

12. The electronic device of claim 10, further comprising:
a carrier electrically connected to the electronic component; and
a redistribution structure between the electronic component and the carrier, wherein the redistribution structure and the non-signal transmitting conductive structure define an opening.

13. The electronic device of claim 12, wherein the redistribution structure comprises a thermally conductive via between the first region of the non-signal transmitting conductive structure and the electronic component.

14. The electronic device of claim 10, further comprising:
a substrate supporting the antenna, wherein the substrate comprises a feed line configured to transmit a feed signal between the electronic component and the antenna, and the electronic component laterally overlaps the feed line.

15. The electronic device of claim 10, wherein the non-signal transmitting conductive structure has a connecting portion connected between the first region and the second region, and the connecting portion is slanted with respected to the second region.

16. An electronic device, comprising:
a carrier;
an electromagnetic radiation structure comprising a radiator and a reflector; and
a heat dissipating structure,
wherein the carrier defines an opening configured to accommodate the reflector and the heat dissipating structure.

17. The electronic device of claim 16, wherein the heat dissipating structure has a surface functioning as the reflector.

18. The electronic device of claim 16, further comprising:
an electronic component, wherein the electronic component has a first terminal configured to transmit a signal and a second terminal configured to transmit a heat.

19. The electronic device of claim 18, further comprising:
a substrate supporting the radiator, wherein the radiator is disposed over a first surface of the substrate, and the electronic component is exposed by the first surface of the substrate.

20. The electronic device of claim 16, wherein the carrier surrounds the heat dissipating structure.
